(19) United States
(12) Patent Application Publication
(10) Pub. No.: US 2012/0139013 A1
(43) Pub. Date: Jun. 7, 2012

(54) STATIC INDUCTION TRANSISTOR WITH DIELECTRIC CARRIER SEPARATION LAYER

(76) Inventors: Sandeep Bahl, Palo Alto, CA (US); Constantin Bulucea, Sunnyvale, CA (US)

(21) Appl. No.: 12/959,736

(22) Filed: Dec. 3, 2010

(51) Int. Cl. H01L 29/808; H01L 21/337

(52) U.S. Cl. 257/266; 438/193; 257/E29.312; 257/E21.445

(57) ABSTRACT

A static induction transistor comprising: a region of semiconductor material having a first conductivity type; at least two spaced-apart gate regions formed in the region of semiconductor material, the gate regions having a second conductivity type that is opposite to the first conductivity type; at least one source region having the first conductivity type formed in the region of semiconductor material between the spaced-apart gate regions; a drain region having the first conductivity type formed in the region of semiconductor and spaced-apart from the source region to define a channel region therebetween; and a dielectric carrier separation layer formed at the periphery of the gate regions.

### FIELD OF THE INVENTION

The present invention relates to semiconductor devices and, in particular, to static induction transistor (SIT) designs that utilize a dielectric carrier separation layer to achieve a lower gate-to-source capacitance and also to prevent direct carrier injection from gate to source when the junction is forward biased. By placing a dielectric layer between the gate and the source, undesirable gate-to-source breakdown can be avoided at smaller gate-to-source separation.

### BACKGROUND

As discussed in U.S. Pat. No. 4,326,209, issued on Apr. 20, 1982, to Nishizawa et al., a static induction transistor (SIT) is a field-effect semiconductor device that is capable of operation at relatively high frequency and power. A SIT is characterized by a short, high resistivity semiconductor channel region that may be controllably depleted of carriers. The current-voltage characteristics of a SIT are generally similar to those of a vacuum tube triode. Devices of this type are also described in U.S. Pat. No. 4,566,172, issued on Jan. 28, 1986, to Bencuya et al.

Referring to FIG. 1, a SIT 100 generally utilizes vertical geometry with a source region 102 of a first conductivity type (n+ in FIG. 1) and a drain region 104 of the first conductivity type (n+ in FIG. 1) formed on opposite sides of a thin, high resistivity layer 106 of the first conductivity type (n in FIG. 1). Gate regions 108 of a conductivity type (p+ in FIG. 1) that is opposite the conductivity type of the source region 102 and the drain region 104 are positioned in the high resistivity layer 106 on opposite sides of the source region 102. During operation, a reverse bias is applied between the gate regions 108 and the remainder of the high resistivity layer 106 causing a depletion region 110 to extend into the channel region that is formed below the source region 102 and between the gate regions 108. As the magnitude of the reverse bias is varied, which in turn causes the extent of the depletion region 110 to vary, the electric field distribution and the resulting source-drain current will also vary. At large enough reverse bias on the gate, the adjacent depletion regions 100 merge, thus interrupting the source-to-drain current flow.

The most critical parameters in a SIT are the spacing between the gate regions 108 and the channel doping level N_{D}. Since most SITs are designed to be normally-on, the channel doping level N_{D} is chosen such that the depletion region 110 from the gate regions 108 does not merge and that there exists, as shown in FIG. 1, a narrow, neutral channel opening 112 with zero gate bias. Typical gaps between the gate regions 108 are a few microns, with channel doping levels N_{D} in the 10¹⁵ cm⁻³ range. The FIG. 1 SIT structure 100 shows the gate regions 108 formed by p-n junctions, but the SIT operations can be generalized to include metal (Schottky) gates or MIS gates. Most SIT devices are fabricated on a silicon (Si) substrate, with gallium arsenide (GaAs) and silicon carbide (SiC) being the next material choices for higher speed operations.

As stated above, in normal mode, a SIT shows triode-like characteristics with high-linearity. A SIT also has a bipolar mode (BSIT). This occurs when the gate region is forward biased past the turn-on voltage of the gate-source junction. High current gains with large current densities are possible in the bipolar mode.

Despite their promise, however, the SIT and BSIT have not yet come into widespread use. This is because, in order to realize their full potential, SIT devices require non-standard processing that is unlikely to be found in standard foundry processes. The current foundry-centric model of production for integrated circuit devices has favored the adoption of power devices that can be fabricated utilizing more conventional processes, and which are thereby more easily monolithically integrable (e.g., LDMOS). Furthermore, conventional CMOS processes lack a good bipolar component. These CMOS processes additionally utilize thin oxides and, therefore, lack a transistor that can withstand a high off-state gate voltage.

Thus, there is a need in a CMOS process for a SIT device with higher gate voltage capability than can be provided by the thin gate oxides currently available. There is also a need for a bipolar-like device with good current gain, but without the extra cost imposed by utilizing a BiCMOS process. The SIT device needs to be fabricated utilizing unit steps used in standard processes to be compatible with the foundry-centric model. It also needs to be planar, since modern foundry processes have stringent planarity requirements.

### SUMMARY

Embodiments of the present invention provide a static induction transistor comprising: a region of semiconductor material having a first conductivity type; at least two spaced-apart gate regions formed in the region of semiconductor material, the gate regions having a second conductivity type that is opposite the first conductivity type; at least one source region having the first conductivity type formed in the region of semiconductor material between the spaced-apart gate regions; a drain region having the first conductivity type formed in the region of semiconductor material and spaced-apart from the source region to define a channel region therebetween; and a dielectric carrier separation layer formed at the periphery of the gate regions.

The features and advantages of the various aspects of the subject matter disclosed herein will be more fully understood and appreciated upon consideration of the following detailed description and the accompanying drawings, which set for illustrative embodiments of the claimed subject matter.

### BRIEF DESCRIPTION OF THE DRAWING

FIG. 1 is a cross section drawing illustrating a conventional planar static induction transistor (SIT).

FIG. 2 is a cross section drawing illustrating an embodiment of an N-type static induction transistor (NSIT) in a conventional CMOS process.

FIG. 3 is a graph showing the output I_{D}-V_{D} characteristics of the FIG. 2 NSIT, as measured on an experimental device in CMOS implementation.

FIG. 4 is a graph showing the output I_{D}-V_{D} characteristics of the FIG. 2 NSIT in bipolar-mode operation, as measured on an experimental device in CMOS implementation.

FIG. 5 is a cross section drawing illustrating an alternate embodiment of an NSIT.

FIG. 6 is cross section drawing illustrating another alternate embodiment of an NSIT.

FIG. 7 is cross section drawing illustrating another alternate embodiment of an NSIT.

FIG. 8 is cross section drawing illustrating another alternate embodiment of an NSIT.

FIG. 9 is a cross section drawing illustrating an embodiment of a P-type static induction transistor (PSIT).

FIG. 10 is a cross section drawing illustrating an alternate embodiment of a PSIT.

FIG. 11 is a cross section drawing illustrating another alternate embodiment of a PSIT.

FIG. 12 is cross section drawing illustrating another alternate embodiment of a PSIT.

FIG. 13 is a cross section drawing illustrating another alternate embodiment of a PSIT.

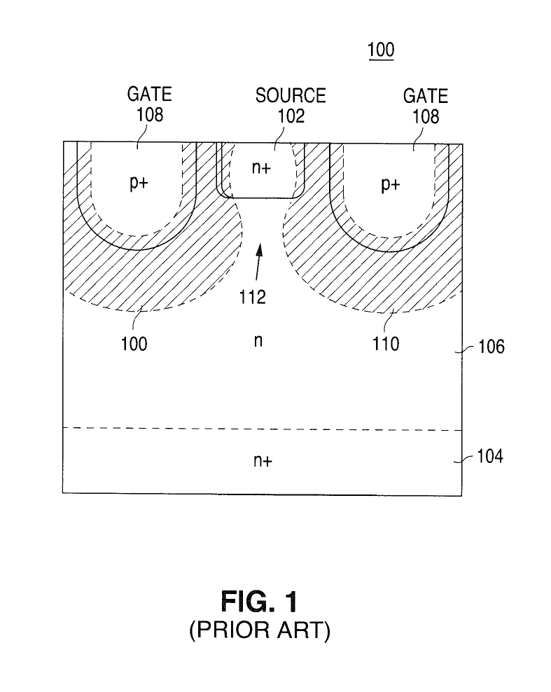

### DETAILED DESCRIPTION

Reference will now be made in detail to embodiments of the invention, examples of which are illustrated in the accompanying drawings. In the following detailed description, specific details are set forth in order to provide a thorough understanding of the present invention. However, it will be apparent to those persons skilled in the art that the present invention may be practiced without these specific details. On other instances, well-known methods, procedures and components have not been described in detail so as not to unnecessarily obscure aspects of the disclosed embodiments.

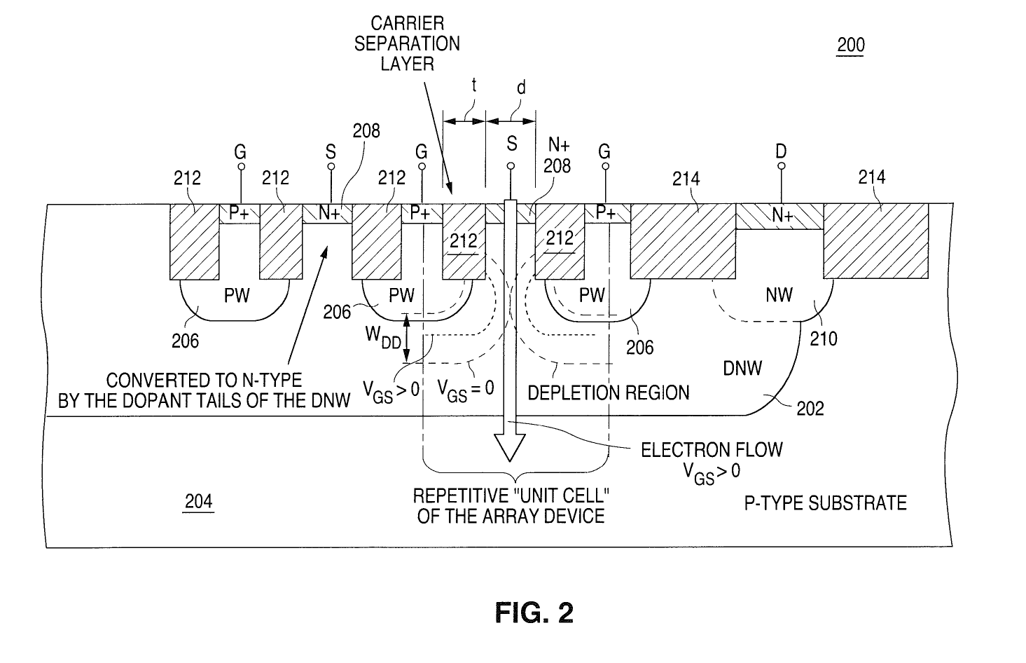

FIG. 2 shows an embodiment of an N-type static induction transistor (NSIT) array device 200 that includes repetitive “unit cells.” The NSIT array device 200 comprises a deep N-type well (DNW) 202 formed in a P-type semiconductor (e.g., silicon) substrate 204. Spaced-apart gate regions in the form of P-type wells (PW) 206 are formed in the N-well 202. N-type source regions 208 are formed in the N-well 202 between the gate regions 206. An N-type drain region in the form of an N-well (NW) 210 is formed in the N-well 202 and spaced-apart from the source regions 208 to define an N-well channel region therebetween. Dielectric (e.g., shallow trench isolation (STI) silicon oxide) carrier separation layers 212 are formed at the periphery of the gate regions 206. In the FIG. 2 embodiment, isolation regions 214 are also formed at the periphery of the drain region 210. As shown in FIG. 2, a heavily doped P+ contact region is formed at the upper surface of each of the P-well gate regions 206 between the dielectric carrier separation layers 212. Also, a heavily doped N+ region is formed at the upper surface of the N-well drain region 210. Well known shallow trench isolation (STI) processes may be utilized to form the dielectric carrier separation layers 212 and the isolation regions 214.

The FIG. 2 NSIT embodiment provides a high gate-voltage capability by virtue of its utilization of a junction-gate, as opposed to an oxide gate. This allows a large gate bias swing in the direction of reverse biasing the junction. Further, the FIG. 2 embodiment provides a high current gain in the direction of forward-biasing the gate. This gain is much higher than from parasitic bipolar typically available in CMOS processes. The high gain is achieved by utilization of the dielectric carrier separation layer 212, which is a vertical insulating barrier having at least three times lower dielectric constant than the adjacent semiconductor material. This has the dual function of keeping the carriers separate at the gate and source contacts, and also reducing the gate-source capacitance.

The “carrier separation layer” is critical to the operation of the SIT. In a conventional SIT, where there is no “carrier separation layer”, the spacing between the adjacent gate junctions, desirably as small as possible for efficient gate control of the channel, is limited, in the low range, by the gate-to-source breakdown voltage. Assuming, to a first approximation, that the n channel region is intrinsic, that the field in the space between the gate and source is constant, and must be smaller than the critical (breakdown) field of silicon:

$${E}_{max} = \frac{\vert {V}_{Gmax} \vert}{a} \leq {E}_{crit ( si )}$$

$$with {E}^{crit ( Si )} \approx 2 \times {10}^{5} V \text{/} cm and \vert {V}_{Gmax} \vert = 10 V$$

$$a \geq \frac{\vert {V}_{Gmax} \vert}{{E}_{crit ( si )}} = \frac{10 V}{2 \times 10 V \text{/} μm} = 0.5 μm$$

With some reasonable margin to breakdown allowance for higher gate voltages, one can safely consider the conditions

a≧1 μm

When the carrier separation layer is introduced, the dimensional restriction on parameter a is severely relaxed, as the silicon dioxide in the “separation layer” 212 can withstand substantially higher fields

E_{crit(SiO2)}=3×10⁵ V/cm=30 V/μm

or

E_{crit(SiO2)}=10×10⁵ v/cm=100 V/μm
(for modern oxides used in STI).
   The distance between the last gate in the array 200 and the NW region 210 around the drain is not critical; it only has to be small enough to keep the series resistance to the drain small.

With continuing reference to FIG. 2, it is noted that the width (t) of the STI trench 212 must be large enough so as to allow safe landing of the gate junction on the bottom of the trench 212. One can formulate the condition where the trench width t is greater than or equal to 2Δ_{reg}, where Δ_{reg} is the registration or alignment accuracy in lithography. A safer condition would be width t greater than or equal to 4Δ_{reg}.

FIG. 2 also shows a distance d between the dielectric carrier separation layers 212 in a SIT unit cell in the SIT array 200. For pinchoff at V_{gs} of approximately 0V, the distance d should be approximately equal to 2WD0, where WDO is the depletion region width in the channel at V_{gs}=0V.

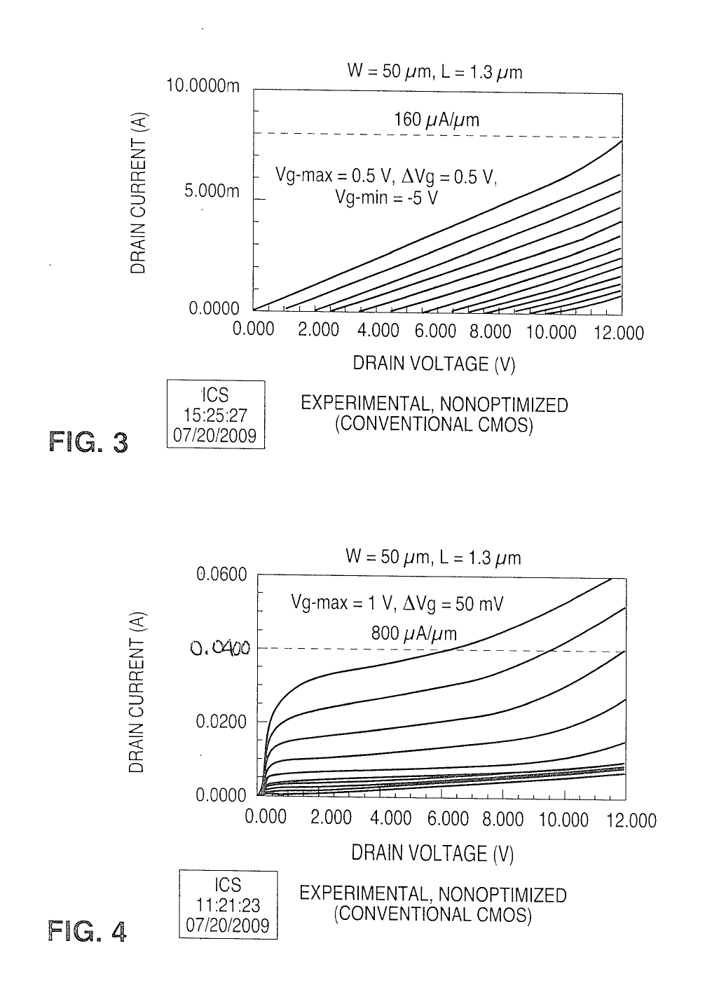

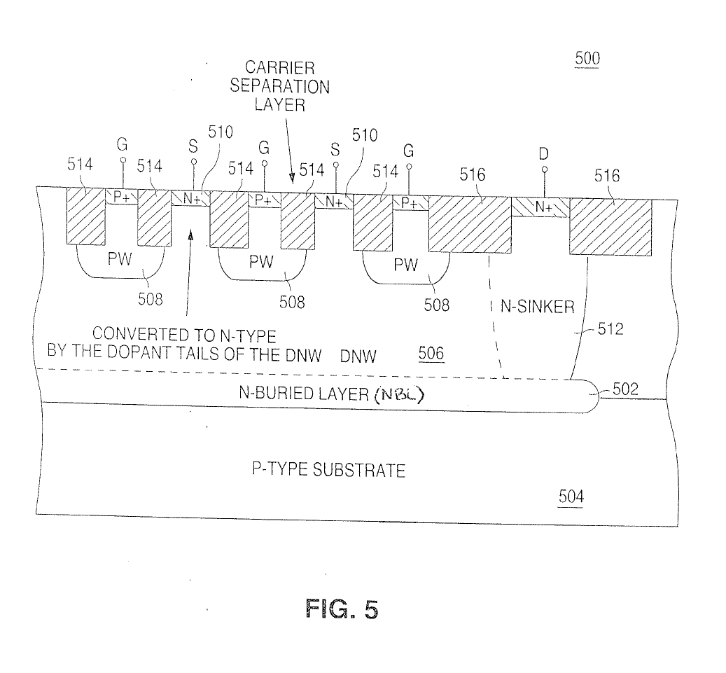

FIGS. 3 and 4 show characterizations of the FIG. 2 NSIT embodiment in both the SIT and B-SIT modes, respectively, where L is the distance between the p-wells of the FIG. 2 embodiment. FIG. 3 shows output I_{D}-V_{D} characteristics of an experimental the NSIT 200, showing the triode characteristics, with I_{D}-max of 150 μA/μm. As shown in FIG. 4, in bipolar (BSIT) mode, high I_{D}-max values of 800 μA/μm can be achieved, while maintaining a good current gain of 20 at a moderate current density of 200 μA/μm. Both I_{D} values are expected to increase when the conventional CMOS process utilized in the experimentation is modified to include a buried N+ layer and an N-type sinker layer (see, for example, FIG. 5).

One of ordinary skill in the art will appreciate that the FIG. 2 NSIT 200 structure may be fabricated utilizing well known CMOS process modules.

FIGS. 5-8, discussed in greater detail below, show alternate NSIT embodiments. As with the FIG. 2 NSIT embodiment, one of ordinary skill in the art will appreciate that the NSIT embodiments shown in FIGS. 5-8 may be fabricated utilizing well known CMOS process modules.

FIG. 5 shows an alternate embodiment of an NSIT 500. The NSIT 500 comprises an N-buried layer (NBL) 502 formed in a P-type semiconductor (e.g., silicon) substrate 504. A deep N-type well (DNW) 506 is formed in the substrate 504 above the N-buried layer 502. Spaced-apart gate regions in the form of P-type wells (PW) 508 are formed in the N-well 506. N-type source regions 510 are formed in the N-well 506 between the gate regions 508. An N-type drain region in the form of an N-sinker region 512 is formed in the N-well 506 and spaced-apart from the source regions 510 to define an N-well channel region therebetween. Dielectric (e.g., shallow trench isolation (STI) silicon oxide) carrier separation layers 514 are formed at the periphery of the gate regions 508. In the FIG. 5 embodiment, STI regions 516 are also formed at the periphery of the drain region 512. Both the N+ buried layer 502 and the N-type sinker layer 512 are added to the FIG. 2 embodiment in order to minimize the series resistance in the path of the drain current.

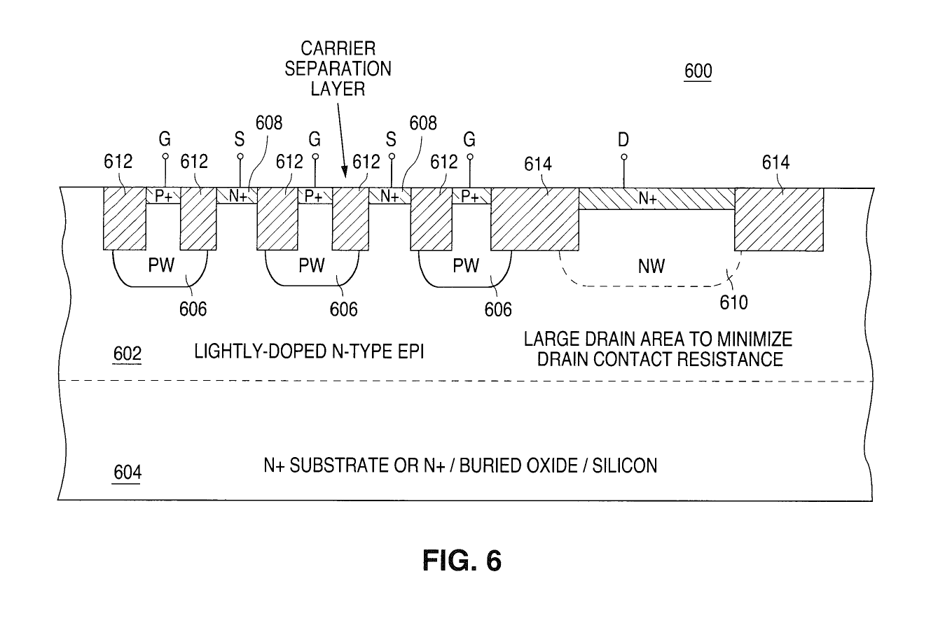

FIG. 6 shows another alternate embodiment of an NSIT 600. The NSIT 600 comprises a lightly-doped n-type epitaxial layer 602 formed on an N+ semiconductor (e.g., silicon) substrate 604. Spaced-apart gate regions in the form of P-type wells (PW) 606 are formed in the epitaxial layer 602. N-type source regions 608 are formed in the epitaxial layer 602 between the gate regions 606. An N-type drain region in the form of an N-well (NW) 610 is formed in the epitaxial layer 602 and spaced-apart from the source regions 608 to define a channel region therebetween. Dielectric (e.g., shallow trench isolation (STI) silicon oxide) carrier separation layers 612 are formed at the periphery of the gate regions 606. In the FIG. 6 embodiment, STI regions 614 are also formed at the periphery of the drain region 610. In the FIG. 6 NSIT 600, the drain region 610 is relatively large to minimize contact resistance to the substrate. The FIG. 6 NSIT 600 improves upon the FIG. 2 NSIT in a 10V CMOS process with added N-type buried layer and N-type sinker regions for reducing the series resistance of the drain. Since this embodiment uses an N+ substrate, special attention must be given to the voltage applied to the substrate, which is no longer isolated from the high potential of the power supply. Alternatively, the FIG. 6 structure can be built on an N+/Buried Oxide/Silicon foundation.

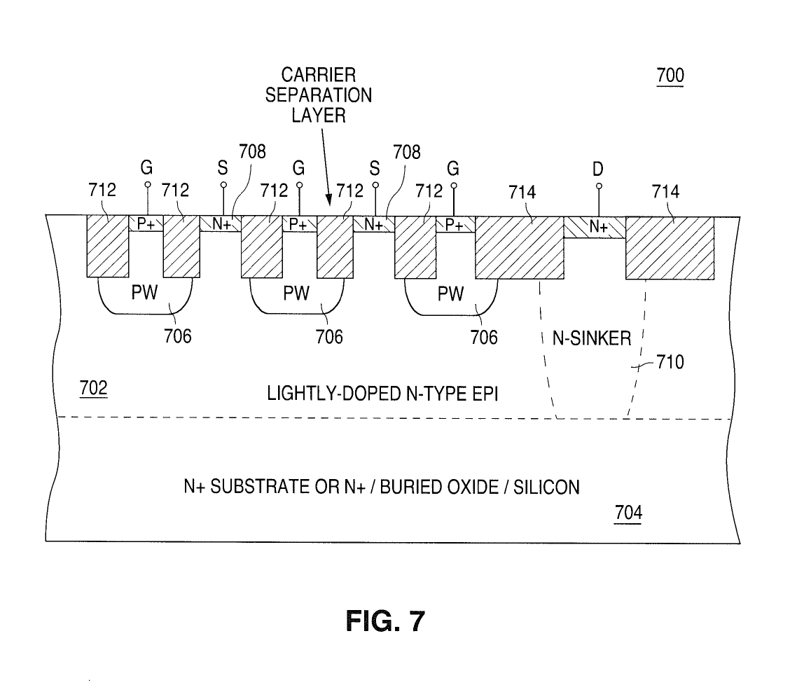

FIG. 7 shows another alternate embodiment of an NSIT 700. The NSIT 700 comprises a lightly-doped n-type epitaxial layer 702 formed on an N+ semiconductor (e.g., silicon) substrate 704. Spaced-apart gate regions in the form of P-type wells (PW) 706 are formed in the epitaxial layer 702. N-type source regions 708 are formed in the epitaxial layer 702 between the gate regions 706. An N-type drain region in the form of an N-sinker region 710 is formed in the epitaxial layer 702 and spaced-apart from the source regions 708 to define a channel region therebetween. Dielectric (e.g., shallow trench isolation (STI) silicon oxide) carrier separation layers 712 are formed at the periphery of the gate regions 706. In the FIG. 7 embodiment, STI regions 714 are also formed at the periphery of the drain region 710. The N-sinker region 710 may be implemented as a combination of n-well or “sinker down” for the top portion of the epi, and “sinker up” for the bottom portion. Since this embodiment uses an N+ substrate, special attention must be given to the voltage applied to the substrate, which is no longer isolated from the high potential of the power supply. Alternatively, the FIG. 7 structure can be built on an N+/Buried Oxide/Silicon foundation.

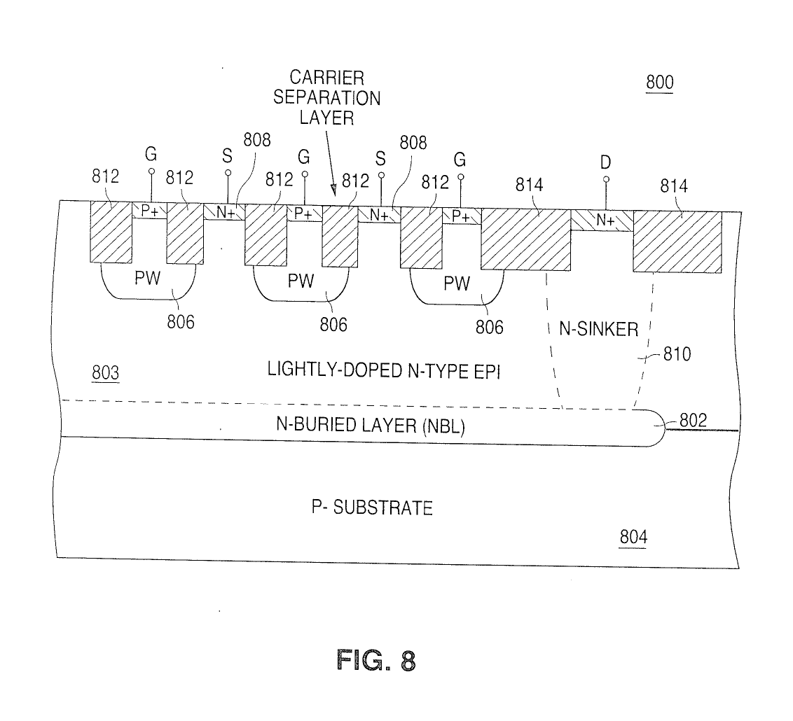

FIG. 8 shows another alternate embodiment of an NSIT 800. The NSIT 800 comprises an N-buried layer (NBL) 802 formed in a lightly-doped n-type epitaxial layer 803 grown on a P-type semiconductor (e.g., silicon) substrate 803. Spaced-apart gate regions in the form of P-type wells (PW) 806 are formed in the epitaxial layer 803 above the N-buried layer 802. N-type source regions 808 are formed in the epitaxial layer 803 between the gate regions 806. An N-type drain region in the form of N-sinker region 810 is formed in the layer 803 and spaced-apart from the source regions 808 to define a channel region therebetween. Dielectric (e.g., shallow trench isolation (STI) silicon oxide) carrier separation layers 812 are formed at the periphery of the gate regions 806. In the FIG. 8 embodiment, STI regions 814 are also formed at the periphery of the drain region 810. The FIG. 8 NSIT 800 is an alternate to the FIG. 7 NSIT 700, the p-type substrate being more commonly used in CMOS processing.

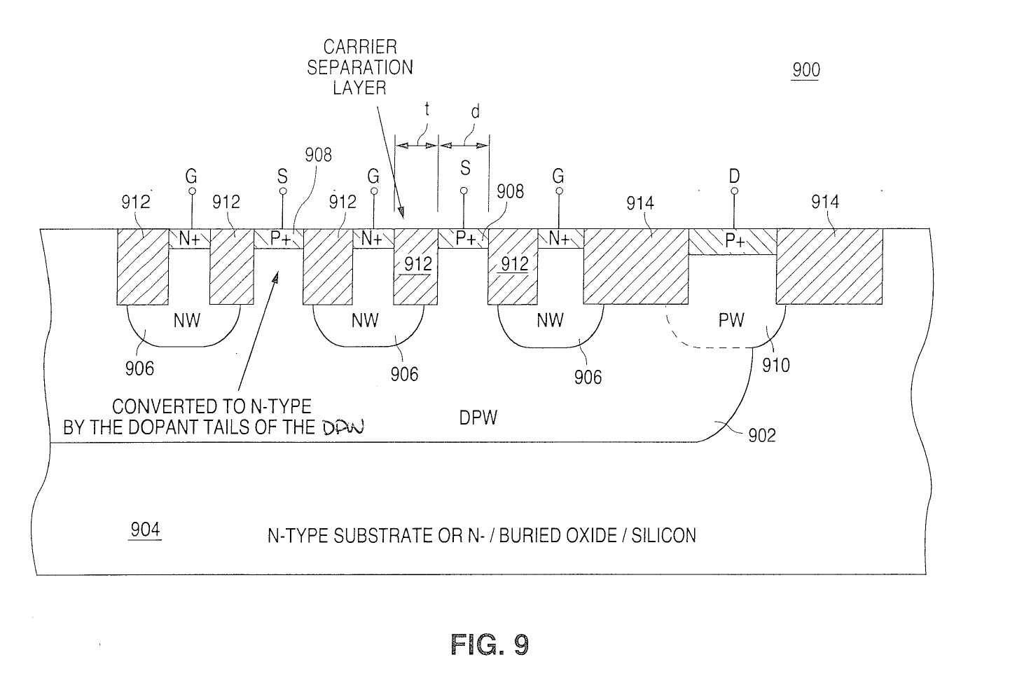

FIGS. 9-13, discussed in greater detail below, show embodiments of P-type static induction transistors (PSIT). Those skilled in the art will appreciate that the PST embodiments shown in FIGS. 9-13 may be fabricated utilizing well know CMOS process modules.

FIG. 9 shows an embodiment of a PSIT 900. The PSIT 900 comprises a deep P-type well (DPW) 902 formed in an N-type semiconductor (e.g., silicon) substrate 904. Spaced-apart gate regions in the form of N-type wells (NW) 906 are formed in the P-well 902. P-type source regions 908 are formed in the P-well 902 between the gate regions 906. An N-type drain region in the form of a P-well (PW) 910 is formed in the P-well 902 and spaced-apart from the source regions 908 to define a P-well channel region therebetween. Dielectric (e.g., shallow trench isolation (STI) silicon oxide) carrier separation layers 912 are formed at the periphery of the gate regions 906. In the FIG. 9 embodiment, STI regions 914 are also formed at the periphery of the drain region 910. Since this embodiment uses an N+ substrate, special attention must be given to the voltage applied to the substrate, which is no longer isolated from the high potential of the power supply. Alternatively, the FIG. 9 structure can be built on an N+/Buried Oxide/Silicon foundation.

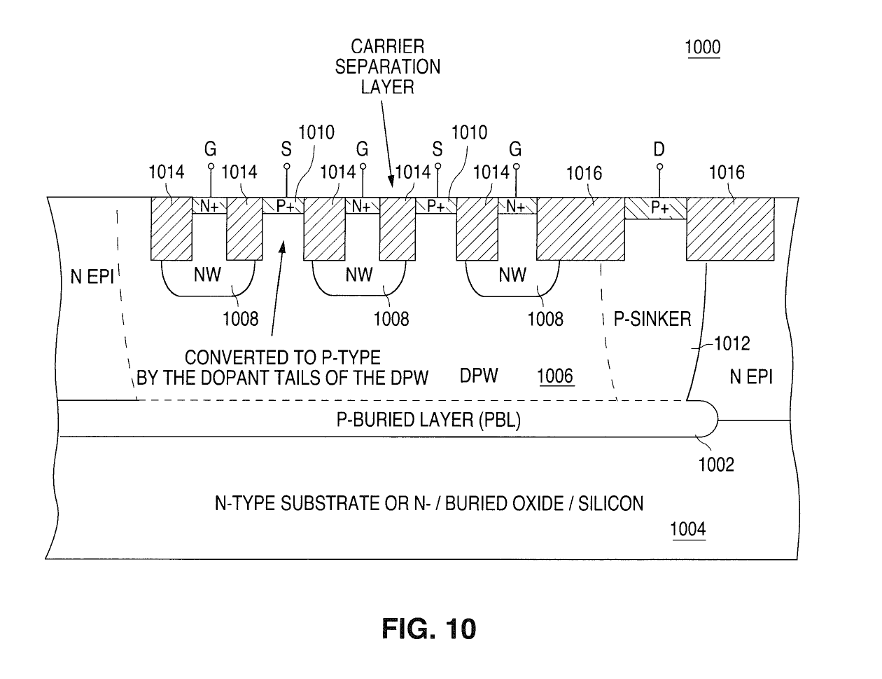

FIG. 10 shows an alternate embodiment of a PSIT 1000. The PSIT 1000 comprises a P-buried layer (PBL) 1002 formed in an N-type semiconductor (e.g., silicon) substrate 1004. A deep P-type well (DPW) 1006 is formed in the substrate 1004 above the P-buried layer 1002. Spaced-apart gate regions in the form of N-type wells (NW) 1008 are formed in the P-well 1006. P-type source regions 1010 are formed in the P-well 1006 between the gate regions 1008. A P-type drain region in the form of a P-sinker region 1012 is formed in the P-well 1006 and spaced-apart from the source regions 1010 to define a P-well channel region therebetween. Dielectric (e.g., shallow trench isolation (STI) silicon oxide) carrier separation layers 1014 are formed at the periphery of the gate regions 1008. In the FIG. 10 embodiment, STI regions 1016 are also formed at the periphery of the drain region 1012. The FIG. 10 PSIT 1000 improves upon the FIG. 9 PSIT 900 in an inverted—polarity CMOS process with added P-type buried layer and P-type sinker for reducing the series resistance of the drain. Since this embodiment uses an N+ substrate, special attention must be given to the voltage applied to the substrate, which is no longer isolated from the high potential of the power supply. Alternatively, the FIG. 10 structure can be built on an N+/Buried Oxide/Silicon foundation.

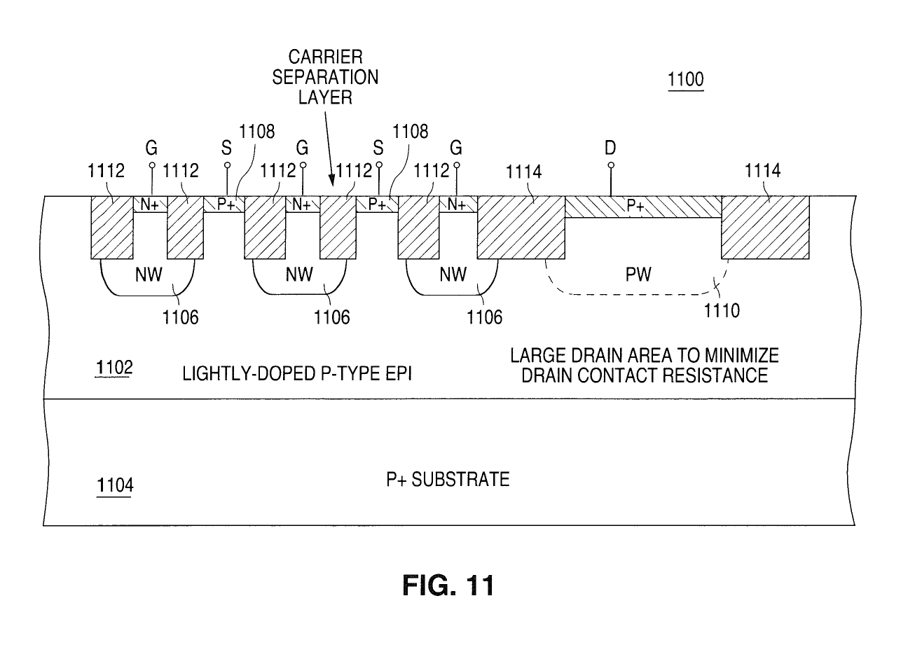

FIG. 11 shows another alternate embodiment of a PSIT 1100. The PSIT 1100 comprises a lightly-doped p-type epitaxial layer formed on a P+ semiconductor (e.g., silicon) substrate 1104. Spaced-apart gate regions in the form of N-type wells (NW) 1106 are formed in the epitaxial layer 1102. P-type source regions 1108 are formed in the epitaxial layer 1102 between the gate regions 1106. A P-type drain region in the form of a P-well (PW) 1110 is formed in the epitaxial layer 1102 and spaced-apart from the source regions 1108 to define a channel region therebetween. Dielectric (e.g., shallow trench isolation (STI) silicon oxide) carrier separation layers 1112 are formed at the periphery of the gate regions 1106. In the FIG. 11 embodiment, STI regions 1114 are also formed at the periphery of the drain region 1110. In the FIG. 11 PSIT 1100, the drain region 1110 is relatively large to minimize contact resistance to the substrate.

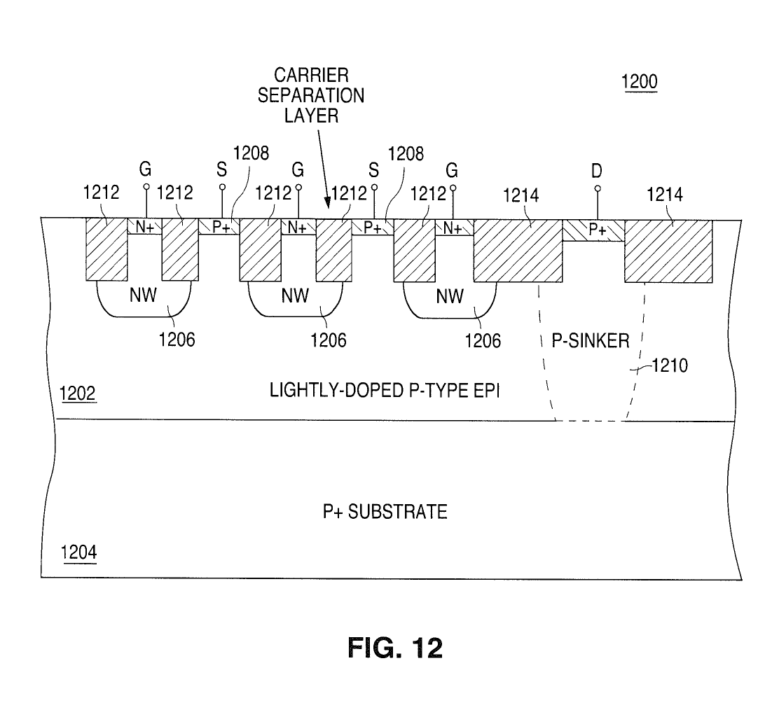

FIG. 12 shows another alternate embodiment of a PSIT 1200. The PSIT 1200 comprises a lightly-doped p-type epitaxial layer 1202 formed on P+ semiconductor (e.g., silicon) substrate 1204. Spaced-apart gate regions in the form of N-type wells (NW) 1206 are formed in the epitaxial layer 1202. P-type source regions 1208 are formed in the epitaxial layer 1202 between the gate regions 1206. A P-type drain region in the form of a P-sinker region 1210 is formed in the epitaxial layer 1202 and spaced-apart from the source regions 1208 to define a channel region therebetween. Dielectric (e.g., shallow trench isolation (STI) silicon oxide) carrier separation layers 1212 are formed at the periphery of the gate regions 1206. In the FIG. 12 embodiment, STI regions 1214 are also formed at the periphery of the drain region 1210. The P-sinker region 1210 may be implemented as a combination of p-well or “sinker down” for the top portion of the epi, and “sinker up” for the bottom portion.

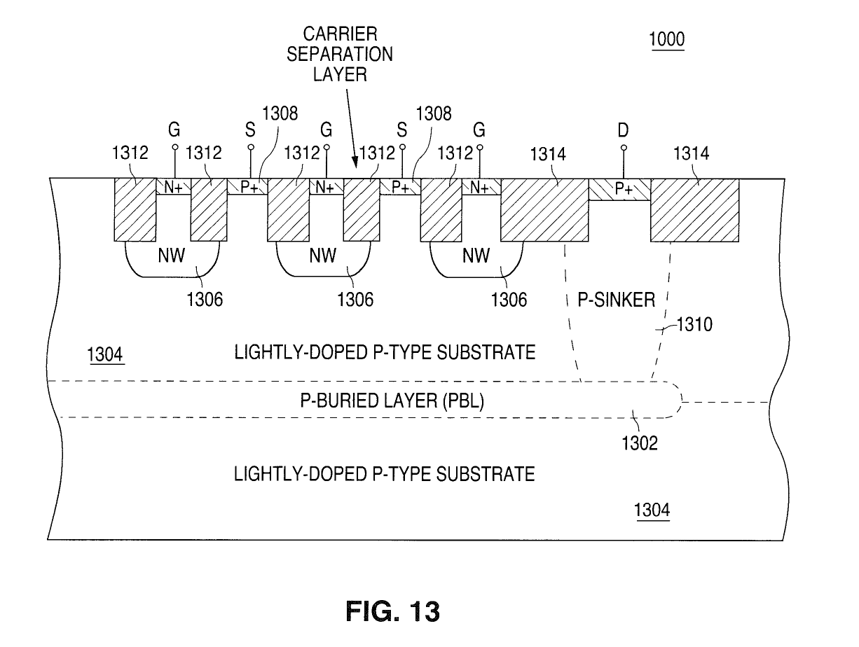

FIG. 13 shows another alternate embodiment of a PSIT 1300. The PSIT 1300 comprises a P-buried layer (PBL) 1302 formed in a lightly-doped p-type semiconductor (e.g., silicon) substrate 1304. Spaced-apart gate regions in the form of N-wells (NW) 1306 are formed in the substrate 1304 above the P-buried layer 1302. P-type source regions 1308 are formed in the substrate 1304 between the gate regions 1306. A P-type drain region in the form of P-sinker region 1310 is formed in the substrate 1304 and spaced-apart from the source regions 1308 to define a channel region therebetween. Dielectric (e.g., shallow trench isolation (STI) silicon oxide) carrier separation layers 1312 are formed at the periphery of the gate regions 1306. In the FIG. 13 embodiment, STI regions 1314 are also formed at the periphery of the drain region 1310. Since this embodiment uses a P-type substrate that is not isolated from the drain region at the surface of the die, special attention must be given to the voltage applied to the substrate, or the substrate is used as a secondary drain electrode. Alternatively, the structure may be built on a P+/Buried Oxide/Silicon foundation.

It should be understood that the particular embodiments of the subject matter described above have been provide by way of example and that other modifications may occur to those skilled in the art without departing from the scope of the claimed subject matter as expressed in the appended claims and their equivalents.

1. A static induction transistor comprising:
a region of semiconductor material having a first conductivity type;
at least two spaced-apart gate regions formed in the region of semiconductor material, the gate regions having a second conductivity type that is opposite the first conductivity type;
at least one source region having the first conductivity type formed in the region of semiconductor material between the spaced-apart gate regions;
a drain region having the first conductivity type formed in an upper surface of the region of semiconductor material and spaced-apart from the source region to define a channel region therebetween; and
a dielectric carrier separation layer formed at the periphery of each gate region.

2. The static induction transistor of claim 1, wherein the dielectric carrier separation layers are spaced-apart by a distance d that is greater than or equal to 2W_{D0}, wherein W_{D0} equals depletion layer thickness at V_{GS}=0.

3. The static induction transistor of claim 1, wherein the first conductivity type is P-type and the second conductivity type is N-type.

4. The static induction transistor of claim 1, wherein the first conductivity type is N-type and the second conductivity type is P-type.

5. A static induction transistor (SIT) comprising:
a P-type silicon substrate having an upper surface;
a deep N-type well region formed in the P-type silicon substrate;
a plurality of spaced-apart P-type well regions formed in the deep N-type well region, each P-type well region having a P+ region formed at an upper surface thereof to define a P-type gate region of the SIT;
at least one N+ source region formed at the upper surface of the deep N-type well between adjacent P-type gate regions;
an N-type well region formed in the upper surface of the P-type silicon substrate at the periphery of the deep N-type well region, the N-type well region having an N+ region formed at an upper surface thereof to define a drain region of the SIT; and
for each P-type gate region, a dielectric carrier separation layer formed at the periphery of the P-type gate region.

6. The SIT of claim 5, wherein the at least one N+ source region has a width d that is greater than or equal to 2W_{D0}, wherein W_{D0} equals the thickness of the SIT depletion layer at V_{GS}=0.

7. A method of forming a static induction transistor (SIT) in a region of semiconductor material having a first conductivity type, the method comprising:
forming at least two spaced-apart gate regions in the semiconductor material, the gate regions having a second conductivity type that is opposite the first conductivity type;
forming at least one source region having the first conductivity type in the semiconductor material between adjacent spaced-apart gate regions:
forming a drain region having the first conductivity type in an upper surface of the semiconductor material and spaced-apart from the source region to define an SIT channel region therebetween; and
for each gate region, a dielectric carrier separation layer formed at the periphery of said gate region.

8. The method of claim 7, wherein the source region has width d that is greater than 2W_{D0}, wherein W_{D0} equals the depletion layer thickness of the SIT at V_{GS}=0.

9. The method of claim 7, wherein the semiconductor material comprises silicon and the dielectric carrier separation layer comprises silicon oxide.
